(19) United States
(12) Patent Application Publication
(10) Pub. No.: US 2023/0298908 A1
(43) Pub. Date: Sep. 21, 2023

(54) HEATING JACKET FOR SEMICONDUCTOR MANUFACTURING EQUIPMENT

(71) Applicant: Samsung Electronics Co., Ltd., Suwon-si (KR)

(72) Inventors: Daewoo Hwangbo, Hwaseong-si (KR); Bogeun Kim, Hwaseong-si (KR); Kyungnam Kang, Hwaseong-si (KR); Changhoon Kwak, Hwaseong-si (KR); Youngju Ro, Hwaseong-si (KR); Joonghoon Lee, Seoul (KR)

(21) Appl. No.: 18/114,235

(22) Filed: Feb. 25, 2023

(30) Foreign Application Priority Data
Mar. 16, 2022 (KR) 10-2022-0032945

(51) Int. Cl. H01L 21/67

(52) U.S. Cl. CPC H01L 21/67017; H01L 21/67248; F16L 59/065

(57) ABSTRACT

A heating jacket wrapping a pipe of semiconductor manufacturing equipment includes an internal shell wrapping an outer circumference of the pipe and having an insulation function, a heating line arranged on the outside of an internal shell, a vacuum insulation panel (VIP) wrapping the outside of the heating line, and an external shell wrapping an external surface of the VIP and having an insulation function. A plurality of heating jackets are connected to one another in a longitudinal direction of the pipe. Temperature sensors are arranged in some of the plurality of heating jackets. Temperature sensors are not arranged in the others of the plurality of heating jackets.

### CROSS-REFERENCE TO RELATED APPLICATION

This application is based on and claims priority under 35 U.S.C. § 119 to Korean Patent Application No. 10-2022-0032945, filed on Mar. 16, 2022, in the Korean Intellectual Property Office, the disclosure of which is incorporated by reference herein in its entirety.

### BACKGROUND

The inventive concept relates to a heating jacket, and more particularly, to a heating jacket for semiconductor manufacturing equipment.

In general, semiconductor manufacturing processes are performed in a vacuum atmosphere of a process chamber of semiconductor manufacturing equipment and, among gases supplied to the process chamber for the semiconductor manufacturing processes, a residual gas and a by-product gas are discharged through a pipe that is a vacuum line. In this process, the residual gas and the by-product gas in the high temperature process chamber pass through the pipe so that temperatures of the residual gas and the by-product gas are reduced and parts of the residual gas and the by-product gas stick to the internal wall of the pipe. That is, because the inside of the process chamber performing the semiconductor manufacturing processes is at a high temperature, the residual gas and the by-product gas may be maintained in a gaseous state. However, because the temperatures of the residual gas and the by-product gas are reduced while moving through the pipe, parts of the residual gas and the by-product gas stick to the internal wall of the pipe so that the diameter of the pipe is reduced and pressure is increased to deteriorate exhaust power.

### SUMMARY

The inventive concept relates to a heating jacket capable of safely discharging a process gas from a pipe, efficiently controlling a by-product in the pipe, reducing power consumption, and preventing a temperature of an external surface from increasing by controlling a surface temperature of the pipe by using a vacuum insulation panel (VIP).

An object to be achieved by the inventive concept is not limited thereto and other objects that are not mentioned may be clearly understood by a person skilled in the art from the following description.

According to an aspect of the inventive concept, there is provided a heating jacket wrapping a pipe of semiconductor manufacturing equipment, including an internal shell wrapping an outer circumference of the pipe and having an insulation function, a heating line arranged on an outside of the internal shell, a VIP wrapping an outside of the heating line, and an external shell wrapping an external surface of the VIP and having an insulation function. A plurality of heating jackets are connected to one another in a longitudinal direction of the pipe. Temperature sensors are arranged in some of the plurality of heating jackets. Temperature sensors are not arranged in the others of the plurality of heating jackets.

According to an aspect of the inventive concept, there is provided a heating jacket provided on the outside of a pipe transferring a gas from semiconductor manufacturing equipment, including an internal shell wrapping an outer circumference of the pipe and having an insulation function, a heating line arranged on an outside of the internal shell, a VIP wrapping the outside of the heating line, and an external shell wrapping an external surface of the VIP and having an insulation function. The pipe comprises an upper level pipe and a lower level pipe. Three or more heating jackets are vertically arranged on the upper level pipe. A smaller number of heating jackets than that of heating jackets arranged on the upper level pipe is arranged on the lower level pipe.

According to an aspect of the inventive concept, there is provided a method of providing a heating jacket for semiconductor manufacturing equipment, including providing a plurality of heating jackets each including a heating line and a VIP wrapping an outside of the heating line between an internal shell having an insulation function and an external shell having an insulation function, arranging the plurality of heating jackets not to overlap one another so that an outside of a pipe, through which a gas is transferred from semiconductor manufacturing equipment, is wrapped, and controlling a temperature of the pipe by applying predetermined power to the heating line. Temperature sensors are arranged in some of the plurality of heating jackets. Temperature sensors are not arranged in the others of the plurality of heating jackets.

### BRIEF DESCRIPTION OF THE DRAWINGS

Embodiments of the inventive concept will be more clearly understood from the following detailed description taken in conjunction with the accompanying drawings in which:

FIG. 1 is a block diagram of a heating jacket for semiconductor manufacturing equipment, according to an example embodiment of the inventive concept;

FIG. 2 is a block diagram of a heating jacket for semiconductor manufacturing equipment, according to another example embodiment of the inventive concept;

FIG. 3 is a perspective view of a state in which a heating jacket for semiconductor manufacturing equipment is provided in a pipe, according to an example embodiment of the inventive concept;

FIG. 4 is a perspective view of a state in which a heating jacket for semiconductor manufacturing equipment is provided in a pipe, according to an example embodiment of the inventive concept;

FIG. 5 is a cross-sectional view illustrating a configuration and temperature distribution of a heating jacket for semiconductor manufacturing equipment, according to an example embodiment of the inventive concept;

FIG. 6 is a perspective view illustrating semiconductor manufacturing equipment in which a heating jacket for the semiconductor manufacturing equipment is provided in a pipe, according to an example embodiment of the inventive concept;

FIG. 7 is a cross-sectional view illustrating a process chamber configuring the semiconductor manufacturing equipment of FIG. 6;

FIGS. 8 to 10 are cross-sectional views illustrating processes of manufacturing a semiconductor device by using the example semiconductor manufacturing equipment of FIG. 6;

FIG. 11 is a flowchart illustrating a method of providing a heating jacket for semiconductor manufacturing equipment, according to an example embodiment of the inventive concept; and

FIG. 12 is a flowchart illustrating a method of exchanging a heating jacket for semiconductor manufacturing equipment, according to an example embodiment of the inventive concept.

### DETAILED DESCRIPTION OF THE EMBODIMENTS

Hereinafter, an embodiment of the inventive concept will be described in detail with reference to the accompanying drawings. Like numbers refer to like elements throughout.

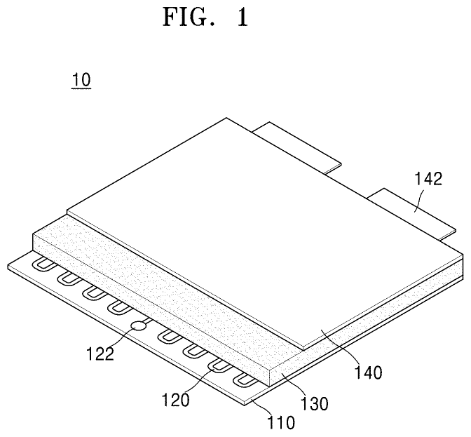

FIG. 1 is a block diagram of a heating jacket 10 for semiconductor manufacturing equipment according to an example embodiment of the inventive concept.

Referring to FIG. 1, the heating jacket 10 includes an internal shell 110 having an insulation function, a heating line 120 arranged on the outside the internal shell 110, a vacuum insulation panel (VIP) 130 wrapping the outside of the heating line 120, and an external shell 140 wrapping the external surface of the VIP 130 and having an insulation function.

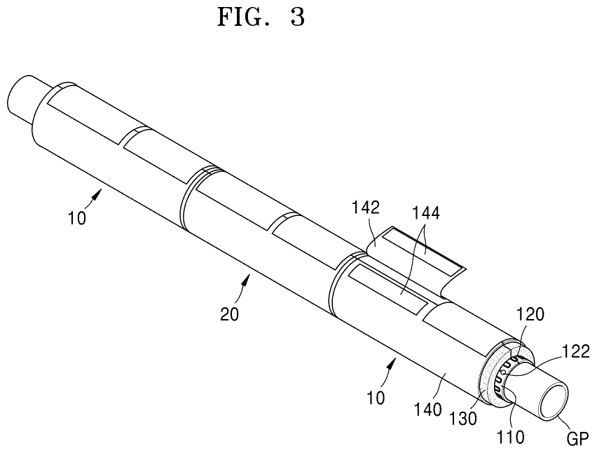

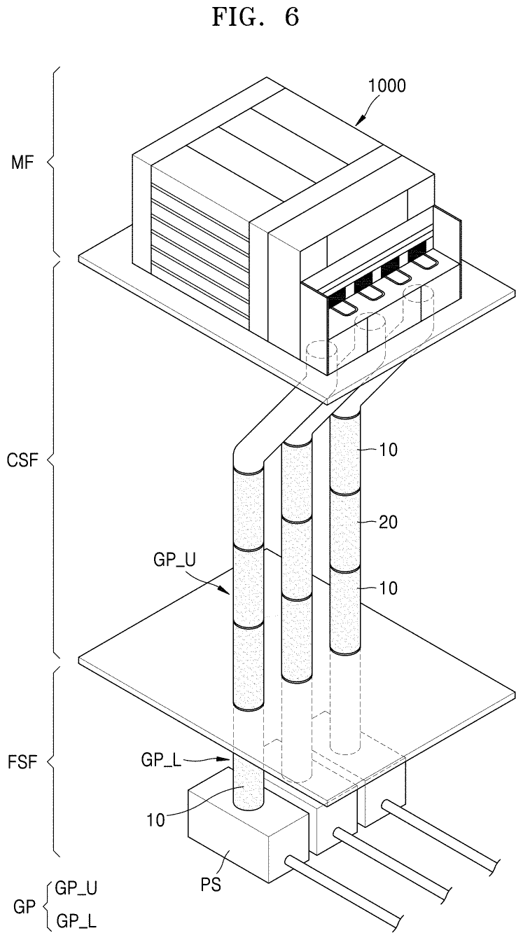

The heating jacket 10 according to the inventive concept is combined with an external surface of a pipe GP (refer to FIG. 3) of semiconductor manufacturing equipment 1000 (refer to FIG. 6) provided in a semiconductor production line to heat the pipe GP (refer to FIG. 3) and to keep a temperature constant.

Highly heat resistant and flexible fabric, such as glass fiber coated with silicon resin or polytetrafluoroethylene (PTFE) resin, is preferably used as the internal shell 110. One of various products released by many companies may be used as PTFE resin as fluorine resin. When the internal shell 110 is coated with silicon resin, the heat resistant temperature of the internal shell 110 may increase.

The heating line 120 may be fixed to the internal shell 110 by using a heating line fixing member (not shown). Therefore, heat generated from the heating line 120 by power supplied from a power supply (not shown) may be transmitted to the pipe GP (refer to FIG. 3). The heating line 120 may extend in zigzags while maintaining a constant distance in a longitudinal or width direction of the internal shell 110.

A temperature sensor 122 is connected to the central point at the highest temperature in the heating line 120 to detect the temperature of the heating line 120. Through the temperature of the heating line 120, which is transmitted by the temperature sensor 122, the temperature of the pipe GP (refer to FIG. 3) is controlled so that it is possible to prevent the residual gas and/or the by-product gas of the semiconductor manufacturing equipment 1000 (refer to FIG. 6) passing through the pipe GP (refer to FIG. 3) from being fixed.

The VIP 130 may surround the outside of the heating line 120. The VIP 130 may include glass fiber therein to pack the glass fiber in a vacuum. Due to the internal vacuum, the thermal conductivity of the VIP 130 may be about 0.002 W/m·k. In addition, the VIP 130 may be compressed to have density in a range of about 250 kg/m³ to about 300 kg/m³. The VIP 130 has very low thermal conductivity and high fire resistance and is light and flexible.

A fine space in the VIP 130 may function as a vacuum insulation space to increase the flexibility of the heating jacket 10. Because the glass fiber has very low thermal conductivity, it is possible to prevent the heat generated by the heating line 120 from radiating to the outside of the external shell 140. A thickness of the VIP 130 may be in a range of about 7 mm to about 11 mm. The thickness of the VIP 130 may be measured in a direction perpendicular to the internal shell 110.

When the thickness of the VIP 130 is less than about 7 mm, it may be difficult to secure sufficient heat blocking characteristics. In addition, when the thickness of the VIP 130 is greater than about 11 mm, the flexibility of the heating jacket 10 may deteriorate so that it may be difficult to process the VIP 130 to meet the pipe of one of various shapes.

Highly heat resistant and flexible fabric, such as glass fiber coated with silicon resin or PTFE resin, is preferably used as the external shell 140. One of various products released by many companies may be used as PTFE resin as fluorine resin. When the external shell 140 is coated with silicon resin, the heat resistant temperature of the external shell 140 may increase.

For example, the internal shell 110 and the external shell 140 may include substantially the same material as each other. In addition, the internal shell 110 and the external shell 140 may have substantially the same thickness as each other. However, the materials and thicknesses of the internal shell 110 and the external shell 140 are not limited thereto.

Fixing covers 142 are formed on one side of the external shell 140. The fixing covers 142 may be formed in plurality on one side of the external shell 140, and fastening members 144 (refer to FIG. 3) may be formed in the same direction as a face direction of the external shell 140 contacting the pipe GP (refer to FIG. 3). Here, the fastening members 144 (refer to FIG. 3) may include Velcro, buttons, or zippers, but the inventive concept is not limited thereto. As used herein, the term “contact” refers to a direct connection (i.e., touching) unless the context indicates otherwise.

The fixing covers 142 are formed to attach the heating jacket 10 to the pipe GP (refer to FIG. 3) when the heating jacket 10 wraps the pipe GP (refer to FIG. 3). For example, when both sides of the external shell 140 contact each other, the fixing covers 142 are attached to the external surface of the external shell 140.

In this case, because other fastening members 144 (refer to FIG. 3) corresponding to the fastening members 144 (refer to FIG. 3) formed in the fixing covers 142 are formed on the external surface of the external shell 140, the heating jacket 10 may be easily detached from the pipe GP (refer to FIG. 3).

Ultimately, the heating jacket 10 for the semiconductor manufacturing equipment according to the inventive concept controls a surface temperature of the pipe GP (refer to FIG. 3) by using the VIP 130 to safely discharge a process gas from the pipe GP (refer to FIG. 3), to efficiently control a by-product in the pipe GP (refer to FIG. 3), to reduce power consumption, and to prevent a temperature of the external surface of the heating jacket 10 from increasing.

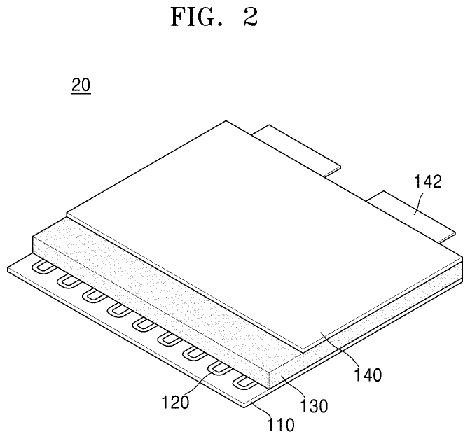

FIG. 2 is a block diagram of a heating jacket 20 for semiconductor manufacturing equipment according to another example embodiment of the inventive concept.

Most components of the heating jacket 20 for the semiconductor manufacturing equipment described hereinafter and materials forming the components are substantially the same as or similar to the components of the heating jacket 10 for the semiconductor manufacturing equipment described with reference to FIG. 1 and the materials forming the components. Therefore, for convenience sake, description will be given based on a difference between the heating jacket 10 for the semiconductor manufacturing equipment and the heating jacket 20 for the semiconductor manufacturing equipment.

Referring to FIG. 2, the heating jacket 20 includes an internal shell 110 having an insulation function, a heating line 120 arranged on the outside the internal shell 110, a VIP 130 wrapping the outside of the heating line 120, and an external shell 140 wrapping the external surface of the VIP 130 and having an insulation function.

The heating jacket 20 according to the current embodiment is combined with an external surface of a pipe GP (refer to FIG. 3) of semiconductor manufacturing equipment 1000 (refer to FIG. 6) provided in a semiconductor production line to heat the pipe GP (refer to FIG. 3) and to keep a temperature constant.

Compared to the heating jacket 10 described above, the heating jacket 20 according to the current embodiment may not include the temperature sensor 122 (refer to FIG. 1). For example, unlike the heating jacket 10 in which the temperature sensor 122 (refer to FIG. 1) is arranged in a part of a region in which the heating line 120 is arranged, the heating jacket 20 according to the current embodiment may include only the heating line 120.

Accordingly, the heating jacket 20 is difficult to be used alone and may be connected to the heating jacket 10 described above to be used. When more than necessary temperature sensors 122 (refer to FIG. 1) are arranged in the one pipe GP (refer to FIG. 3), cost in accordance with operation of unnecessary temperature sensors 122 (refer to FIG. 1) arises so that a cost reduction effect may be offset. Therefore, some of the plurality of heating jackets 10 and 20 wrapping the one pipe GP (refer to FIG. 3) may include the heating jacket 20 that does not include the temperature sensor 122 (refer to FIG. 1) so that the cost reduction effect may be maximized.

FIG. 3 is a perspective view of a state in which a heating jacket for semiconductor manufacturing equipment according to an example embodiment of the inventive concept is provided in a pipe GP.

Referring to FIG. 3, the plurality of heating jackets 10 and 20 are connected to one another in a longitudinal direction of the pipe GP.

The temperature sensors 122 may be arranged in some of the plurality of heating jackets 10 and 20 and may not be arranged in the others of the plurality of heating jackets 10 and 20. Through the temperature of the heating line 120, which is transmitted by the temperature sensor 122, the temperature of the pipe GP is controlled so that it is possible to prevent the residual gas and/or the by-product gas of the semiconductor manufacturing equipment 1000 (refer to FIG. 6) passing through the pipe GP from being fixed. Specifically, the one heating jacket 20 may be arranged between the two heating jackets 10 in the longitudinal direction of the pipe GP. However, the arrangement of the plurality of heating jackets 10 and 20 is not limited thereto.

The plurality of heating jackets 10 and 20 may wrap the pipe GP without overlapping one another. For example, the plurality of heating jackets 10 and 20 may be provided on the pipe GP to encircle the pipe GP. Each of the plurality of heating jackets 10 and 20 may be detached independently from the pipe GP by the fixing covers 142 and the fastening members 144. In other words, only some of the plurality of heating jackets 10 and 20 may be exchanged.

For example, only defective heating jackets 10 and 20 may be exchanged in a process of periodically performing maintenance inspection on the plurality of heating jackets 10 and 20. Accordingly, cost required for the maintenance of the pipe GP of the semiconductor manufacturing equipment 1000 (refer to FIG. 6) may be reduced.

In addition, the heating jacket 20 that does not include the temperature sensor 122 is difficult to be used alone and may be connected to the heating jacket 10 including the temperature sensor 122 to be used. When more than necessary temperature sensors 122 are arranged in the one pipe GP, cost in accordance with operation of unnecessary temperature sensors 122 arises so that a cost reduction effect may be offset. Therefore, some of the plurality of heating jackets 10 and 20 wrapping the one pipe GP may include the heating jacket 20 that does not include the temperature sensor 122 so that the cost required for the maintenance of the pipe GP of the semiconductor manufacturing equipment 1000 may be remarkably reduced.

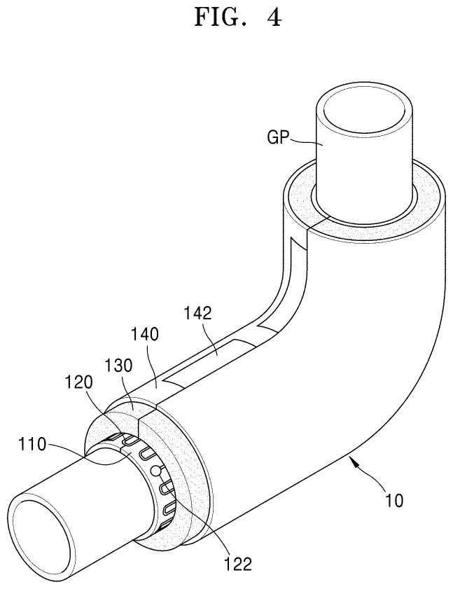

FIG. 4 is a perspective view of a state in which the heating jacket 10 for the semiconductor manufacturing equipment according to an example embodiment of the inventive concept is provided in the pipe GP.

Referring to FIG. 4, the heating jacket 10 is arranged along the bent pipe GP. For example, the heating jacket 10 may be provided on the pipe GP to encircle the pipe GP.

The temperature sensor 122 may be arranged in the heating jacket 10. Through the temperature of the heating line 120, which is transmitted by the temperature sensor 122, the temperature of the pipe GP is controlled so that it is possible to prevent the residual gas and/or the by-product gas of the semiconductor manufacturing equipment 1000 (refer to FIG. 6) passing through the pipe GP from being fixed.

The heating jacket 10 includes the VIP 130 and the fine space in the VIP 130 functions as the vacuum insulation space to increase the flexibility of the heating jacket 10. The thickness of the VIP 130 may be in a range of about 7 mm to about 11 mm.

When the thickness of the VIP 130 is less than about 7 mm, it may be difficult to secure sufficient heat blocking characteristics. In addition, when the thickness of the VIP 130 is greater than about 11 mm, the flexibility of the heating jacket 10 may deteriorate so that it may be difficult to process the VIP 130 to meet the pipe of one of various shapes.

In the heating jacket 10 for the semiconductor manufacturing equipment according to the inventive concept, it is possible to secure sufficient heat blocking characteristics and flexibility by controlling the thickness of the VIP 130. Therefore, because the heating jacket 10 may be provided in the bent pipe GP, it may be efficient for the maintenance of the pipe GP of the semiconductor manufacturing equipment 1000 regardless of the shape of the pipe GP of the semiconductor manufacturing equipment 1000.

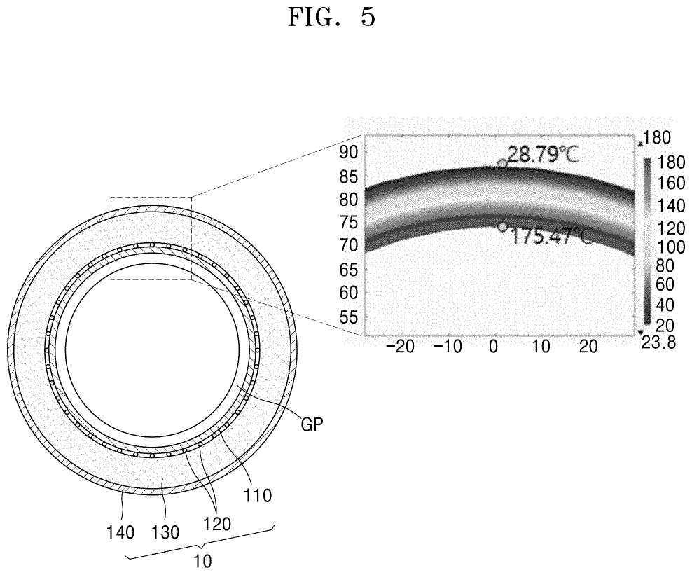

FIG. 5 is a cross-sectional view illustrating a configuration and temperature distribution of the heating jacket 10 for the semiconductor manufacturing equipment according to an example embodiment of the inventive concept.

Referring to FIG. 5, in order to examine the effect of the heating jacket 10 for the semiconductor manufacturing equipment through simulation, the heating jacket 10 arranged on the pipe GP, to which an internal diameter, a thickness, and a length under actually used conditions are applied, is assumed.

Before performing the simulation, thicknesses, densities, and thermal conductivity characteristics of the materials forming the heating jacket 10 are secured and power required to increase an internal temperature of the pipe GP to be in a range of about 170° C. to about 190° C. and an external temperature of the external shell 140 in accordance with the power are examined.

The left part of FIG. 5 illustrates a cross-section of the heating jacket 10 set for the simulation. It is assumed that constant heat loss caused by convection occurs in the outside of the external shell 140 and in the pipe GP. In addition, it is assumed that the internal shell 110 and the external shell 140 have the same thickness, density, and thermal conductivity characteristics as each other.

The right part of FIG. 5 illustrates a heat distribution simulation result. When predetermined power is applied to the heating jacket 10 so that the internal temperature of the pipe GP reaches 175.47° C., the external temperature of the external shell 140 is measured at 28.79° C. In this case, the inventors could determine that the external temperature of the external shell 140 may be controlled to be very low compared to that of a common heating jacket in which the VIP 130 is not used while power consumption is reduced by about 25%.

For example, when a simulation result of power input at the same temperature is observed, the inventors could determine that the power efficiency of the heating jacket 10 including the VIP 130 increases.

When a heat distribution simulation result of a common heating jacket that does not include the VIP 130 and the heat distribution simulation result of the heating jacket 10 including the VIP 130 are analyzed, the inventors could determine that thermal conductivity of heat transmitted to the external shell 140 of the heating jacket 10 including the VIP 130 is not high so that the external temperature of the external shell 140 is in a range capable of securing safety of workers.

For example, the inventors could determine that the external temperature of the heating jacket 10 is controlled to be no more than about 40° C. when the internal temperature of the pipe GP is controlled to be in a range of about 80° C. to about 180° C. Here, because the safety of workers may be secured when the external temperature of the heating jacket 10 is controlled to be no more than about 40° C., the work efficiency and work safety of the maintenance of the pipe GP may be remarkably increased.

FIG. 6 is a perspective view illustrating semiconductor manufacturing equipment 1000 in which a heating jacket for semiconductor manufacturing equipment according to an example embodiment of the inventive concept is provided in a pipe.

Referring to FIG. 6, a main fab MF in which the semiconductor manufacturing equipment 1000 is arranged and a clean subfab CSF and a facility subfab (FSF) arranged under the main fab MF are schematically illustrated.

The main fab MF, in which the semiconductor manufacturing equipment 1000 is arranged, is clean at a significant level. In the main fab MF, in which a semiconductor process is actually performed, most process workers perform works and operation and maintenance of the semiconductor manufacturing equipment 1000 are performed.

In the clean subfab CSF as a layer under the main fab MF, ancillary equipment helping the semiconductor manufacturing equipment 1000 operate may be arranged. Specifically, a generator applying power to the semiconductor manufacturing equipment 1000, a chiller maintaining a constant temperature in the semiconductor manufacturing equipment 1000, a switchboard, a gas supply, and upper level pipes GP_U through which various gases pass may be arranged.

In the facility subfab FSF as a layer under the clean subfab CSF, pumps/scrubbers PS and lower level pipes GP_L connecting the pump/scrubber PS to the upper level pipes GP_U may be arranged. Cleanliness of the facility subfab FSF may not be managed. Specifically, the pump maintains a constant pressure or creates a vacuum in the semiconductor manufacturing equipment 1000 and the scrubber burs various by-products remaining after the semiconductor process is completed to discharge contaminants.

The pipe GP may include the upper level pipes GP_U and the lower level pipes GP_L, three or more heating jackets 10 and 20 may be vertically arranged on each of the upper level pipes GP U, and a smaller number of heating jackets 10 than that of heating jackets 10 arranged on each of the upper level pipes GP_U may be arranged on each of the lower level pipes GP_L. For example, the plurality of heating jackets 10 and 20 may be provided on each of the upper level pipes GP_U to encircle the upper level pipes GP_U, and a smaller number of heating jackets 10 may be provided on each of the lower level pipes GP_L to encircle the lower level pipes GP_L.

Here, the temperature sensors 122 (refer to FIG. 1) may be arranged in some of the plurality of heating jackets 10 and 20 provided on the upper level pipes GP_U and may not be arranged in the others of the plurality of heating jackets 10 and 20 provided on the upper level pipes GP_U.

The plurality of heating jackets 10 and 20 may vertically contact one another without overlapping one another. For example, adjacent ends of the plurality of heating jackets 10 and 20 may contact one another. A vertical length of one heating jacket 10 or 20 may be about 2 m. However, the inventive concept is not limited thereto. Each of the plurality of heating jackets 10 and 20 may be independently detached from each of the upper level pipes GP_U and the lower level pipes GP_L by the fixing covers 142 and the fastening members 144 that are vertically arranged.

In the clean subfab CSF and the facility subfab FSF configured as described above, when the internal temperature of the pipe GP is controlled to be in a range of about 80° C. to about 180° C., the external temperature of each of the plurality of heating jackets 10 and 20 may be controlled to be no more than about 40° C. Therefore, because the external temperature of the heating jacket 10 is controlled to be no more than about 40° C., the safety of workers may be secured and the work efficiency and work safety of the maintenance of the pipe GP may be remarkably increased.

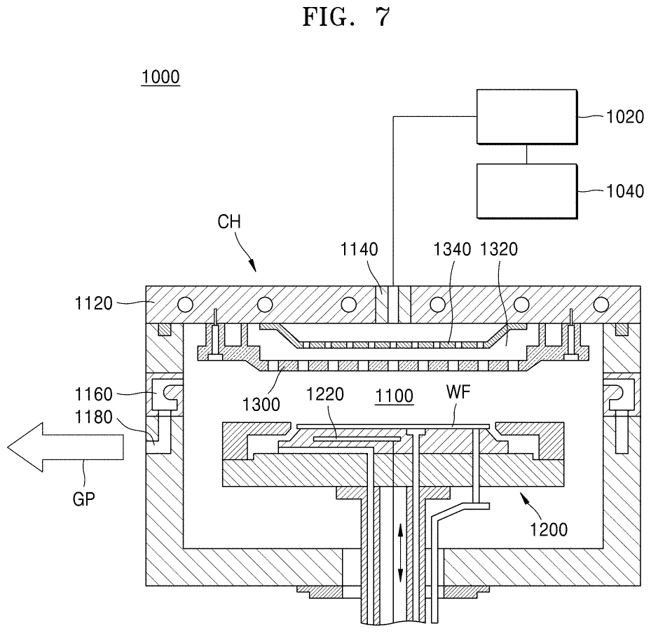

FIG. 7 is a cross-sectional view illustrating a process chamber CH configuring the semiconductor manufacturing equipment 1000 of FIG. 6.

The process chamber CH may be a part of chemical vapor deposition (CVD) equipment. The process chamber CH includes side walls, a bottom, and a cover 1120 forming a chamber internal region 1100. The side walls and the bottom are generally prepared as a single aluminum (Al) block. The side walls may include a conduit (not shown), and a fluid for controlling a temperature of the side walls may flow through the conduit. In addition, the process chamber CH may include a pumping ring 1160 connecting the chamber internal region 1100 to an exhaust port 1180.

A substrate support member 1200, of which temperature may be controlled, may be arranged near the center of the chamber internal region 1100. The substrate support member 1200 supports the semiconductor substrate WF in a process of forming the thin film. In general, the substrate support member 1200 may be formed of Al, ceramic, or a combination of Al and ceramic and may include a vacuum port (not shown) and at least one heating member 1220.

The semiconductor substrate WF may be fixed to the substrate support member 1200 in the process of forming the thin film by applying a vacuum between the semiconductor substrate WF and the substrate support member 1200 by using the vacuum port. The heating member 1220 may be arranged in the substrate support member 1200 to heat the substrate support member 1200 and the semiconductor substrate WF thereon to a constant temperature.

The cover 1120 may be supported by the side walls and may be separated for the maintenance of the process chamber CH. In general, the cover 1120 may be formed of Al and may include a conduit therein, through which a fluid for controlling a temperature of the cover 1120 may flow.

A mixed block 1140 may be arranged in the cover 1120. The mixed block 1140 may be connected to a gas supply 1020. In general, individual gases supplied from the gas supply 1020 are combined in the mixed block 1140. Because these gases are mixed with one another into a single homogeneous gas flow in the mixed block 1140 and the single homogeneous gas flow is supplied to the chamber internal region 1100 through a shower head 1300.

The shower head 1300 may be connected to the cover 1120. In addition, a perforated blocker plate 1340 may be optionally arranged in a shower head internal region 1320 between the shower head 1300 and the cover 1120. A gas to be supplied to the chamber internal region 1100 through the mixed block 1140 is first spread by the perforated blocker plate 1340. Then, the gas is supplied to the chamber internal region 1100 through the shower head 1300. The perforated blocker plate 1340 and the shower head 1300 provide a uniform gas flow to the chamber internal region 1100. The uniform gas flow promotes the formation of a uniform thin film on the semiconductor substrate WF.

A gas line for supplying a process gas from the gas supply 1020 to the chamber internal region 1100 may include a valve (not shown) for diverting a gas flow. In addition, the gas supply 1020 may be controlled by a gas controller 1040. For example, the gas controller 1040 may control a kind of the gas supplied to the chamber internal region 1100, a supply point and an end point of the gas, and the gas flow by controlling the gas supply 1020.

A process of supplying the gas to the process chamber CH to form the thin film will be described as follows. The semiconductor substrate WF is brought into the process chamber CH and is mounted on the substrate support member 1200. In the semiconductor substrate WF, a plurality of uneven patterns may be formed and an insulating layer is formed on the plurality of uneven patterns. Next, according to the control of the gas controller 1040, a predetermined amount of process gas is supplied from the gas supply 1020 to the mixed block 1140 and is uniformly supplied from the shower head 1300 to the chamber internal region 1100. At the same time, by exhausting an atmosphere of the chamber internal region 1100 to the exhaust port 1180, the heating member 1220 in the substrate support member 1200 is driven while maintaining the chamber internal region 1100 with a predetermined pressure to radiate heat energy. The radiated heat energy may heat an upper portion of the substrate support member 1200 and may heat the semiconductor substrate WF mounted in the substrate support member 1200 to a predetermined temperature. The supplied process gas may cause a chemical reaction so that the thin film may be formed on a front surface of the semiconductor substrate WF.

In general, the semiconductor manufacturing processes are performed in the vacuum atmosphere of the process chamber CH of the semiconductor manufacturing equipment 1000 and, among the gases supplied to the process chamber CH for the semiconductor manufacturing processes, the residual gas and the by-product gas are discharged through the pipe GP that is the vacuum line.

In this process, the residual gas and the by-product gas in the high temperature process chamber CH pass through the pipe GP so that temperatures of the residual gas and the by-product gas are reduced and parts of the residual gas and the by-product gas stick to the internal wall of the pipe GP. For example, because the inside of the process chamber CH performing the semiconductor manufacturing processes is at a high temperature, the residual gas and the by-product gas may be maintained in a gaseous state. However, because the temperatures of the residual gas and the by-product gas are reduced while moving through the pipe GP, parts of the residual gas and the by-product gas stick to the internal wall of the pipe GP so that the diameter of the pipe GP is reduced and pressure is increased to deteriorate exhaust power.

Ultimately, the heating jacket 10 for the semiconductor manufacturing equipment according to the inventive concept controls the surface temperature of the pipe GP by using the VIP 130 (refer to FIG. 1) to safely discharge the process gas from the pipe GP, to efficiently control the by-product in the pipe GP, to reduce power consumption, and to prevent the temperature of the external surface of the heating jacket 10 from increasing.

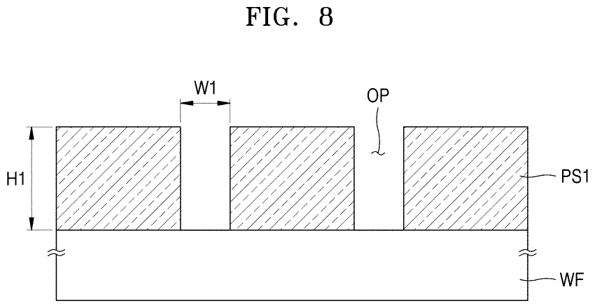

FIGS. 8 to 10 are cross-sectional views illustrating processes of manufacturing a semiconductor device by using the example semiconductor manufacturing equipment of FIG. 6.

Referring to FIG. 8, by forming a preliminary structural layer on the top surface of the semiconductor substrate WF and performing a photolithography process and an etching process until a part of the top surface of the semiconductor substrate WF is exposed, a first structural layer PSI including openings OP is formed on the top surface of the semiconductor substrate WF.

The semiconductor substrate WF may include silicon (Si), germanium (Ge), silicon carbide (SiC), gallium arsenide (GaAs), or indium arsenide (InAs). In some embodiments, the semiconductor substrate WF may have a silicon on insulator (SOI) structure. In addition, the semiconductor substrate WF may include a conductive region, for example, a well doped with impurities or a structure doped with impurities. In addition, the semiconductor substrate WF may include one of various device isolation structures, such as a shallow trench isolation (STI) structure.

In some embodiments, the first structural layer PSI may include an insulating material. In other embodiments, the first structural layer PSI may include a conductive material. A material forming the first structural layer PS1 may vary depending on a purpose.

Each of the openings OP may have a high aspect ratio. The first structural layer PSI may have a height H1 and each of the openings OP may have a width W1. As a semiconductor device has large capacity and is highly integrated, an area of a unit memory element is minimized so that the openings OP each having the high aspect ratio may be formed.

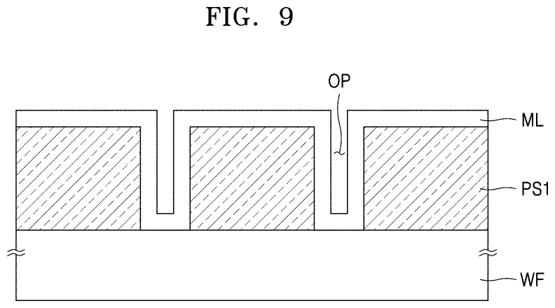

Referring to FIG. 9, a material layer ML is conformally formed on the top surface of the first structural layer PS1, side surfaces of the first structural layer PS1, and the exposed top surface of the semiconductor substrate WF.

The semiconductor manufacturing equipment 1000 (refer to FIG. 7) may be used to conformally form the material layer ML in substantially the same thickness along a space limited by the openings OP each having the high aspect ratio.

The thickness of the material layer ML may be in a range of about 40 Å to about 200 Å. However, the inventive concept is not limited thereto. The thickness of the material layer ML may vary depending on a purpose.

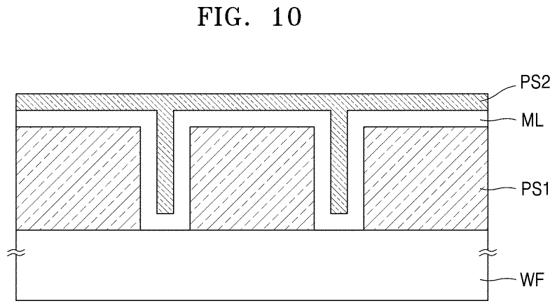

Referring to FIG. 10, by forming a second structural layer PS2 on the material layer ML, the space limited by the openings OP (refer to FIG. 9) may be completely filled.

The second structural layer PS2 may include a material different from that of the first structural layer PS1. The material forming the second structural layer PS2 may vary depending on a purpose.

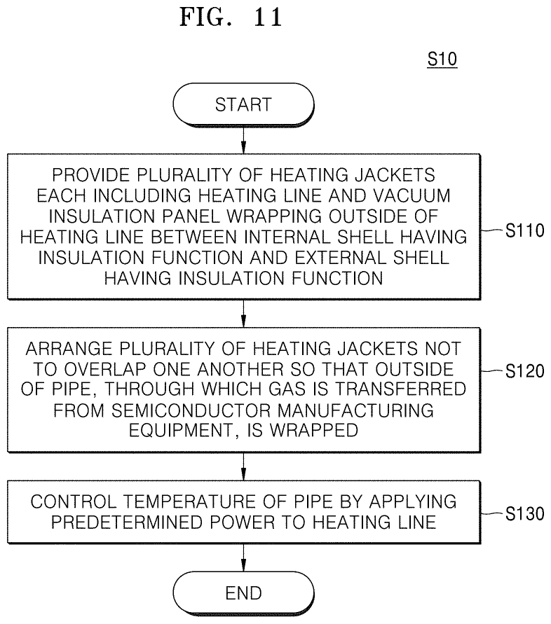

FIG. 11 is a flowchart illustrating a method S10 of providing a heating jacket for semiconductor manufacturing equipment, according to an example embodiment of the inventive concept.

Referring to FIG. 11, the method S10 of providing the heating jacket for the semiconductor manufacturing equipment may include processes S110 to S130.

If a certain embodiment may be differently implemented, a specific process order may vary. For example, two continuous processes may be simultaneously performed or may be performed in the opposite order as described.

The method S10 of providing the heating jacket for the semiconductor manufacturing equipment may include operation S110 of providing a plurality of heating jackets 10 and 20 each including a heating line 120 and a VIP 130 wrapping the outside of the heating line between an internal shell 110 having an insulation function and an external shell 140 having an insulation function, operation S120 of arranging the plurality of heating jackets 10 and 20 not to overlap one another so that the outside of a pipe GP, through which a gas is transferred from the semiconductor manufacturing equipment, is wrapped, and operation S130 of controlling a temperature of the pipe GP by applying predetermined power to the heating line 120.

Here, the plurality of heating jackets may include the heating jackets 10 and 20 described above. In addition, the pipe may include the pipe GP included in the semiconductor manufacturing equipment 1000 described above.

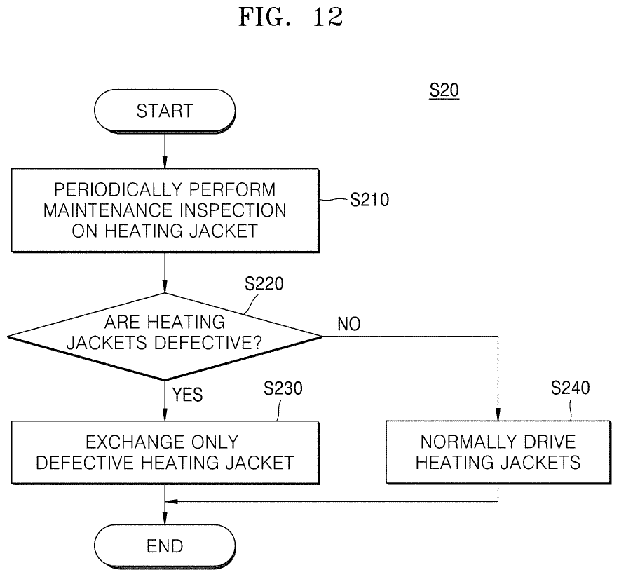

FIG. 12 is a flowchart illustrating a method S20 of exchanging a heating jacket for semiconductor manufacturing equipment, according to an example embodiment of the inventive concept.

Referring to FIG. 12, the method S20 of exchanging the heating jacket for the semiconductor manufacturing equipment may include processes S210 to S240.

If a certain embodiment may be differently implemented, a specific process order may vary. For example, two continuous processes may be simultaneously performed or may be performed in the opposite order as described.

The method S20 of exchanging the heating jacket for the semiconductor manufacturing equipment may include operation S210 of periodically performing maintenance on heating jackets, operation S220 of determining whether the heating jackets are defective, operation S230 of exchanging only defective heating jackets, and operation S240 of normally driving the heating jackets.

Here, the plurality of heating jackets may include the heating jackets 10 and 20 described above. In addition, the pipe may include the pipe GP included in the semiconductor manufacturing equipment 1000 described above.

As a result, in a method of exchanging the heating jacket for the semiconductor manufacturing equipment, according to the inventive concept, because only defective heating jackets may be exchanged in a process of periodically performing maintenance on heating jackets, expenses required for maintenance of the pipe of the semiconductor manufacturing equipment may be reduced.

While the inventive concept has been particularly shown and described with reference to embodiments thereof, it will be understood that various changes in form and details may be made therein without departing from the spirit and scope of the following claims.

What is claimed is:

1. A heating jacket wrapping a pipe of semiconductor manufacturing equipment, the heating jacket comprising:
an internal shell wrapping an outer circumference of the pipe and having an insulation function;
a heating line arranged on an outside of the internal shell;
a vacuum insulation panel (VIP) wrapping an outside of the heating line; and
an external shell wrapping an external surface of the VIP and having an insulation function, wherein a plurality of heating jackets are connected to one another in a longitudinal direction of the pipe, wherein temperature sensors are arranged in some of the plurality of heating jackets, and wherein temperature sensors are not arranged in the others of the plurality of heating jackets.

2. The heating jacket of claim 1, wherein the plurality of heating jackets wrap the pipe without overlapping one another.

3. The heating jacket of claim 2, wherein the plurality of heating jackets are independently detachable from the pipe by fastening members, respectively.

4. The heating jacket of claim 3, wherein only some of the plurality of heating jackets are exchangeable.

5. The heating jacket of claim 1, wherein the VIP includes glass fiber therein, and wherein thermal conductivity of the VIP is about 0.002 W/m·k.

6. The heating jacket of claim 5, wherein the VIP is compressed to have density in a range of about 250 kg/m³ to about 300 kg/m³.

7. The heating jacket of claim 1, wherein the internal shell and the external shell include substantially the same material as each other, and wherein the internal shell and the external shell have substantially the same thickness as each other.

8. The heating jacket of claim 1, further comprising:
a power supply connected to the heating line, wherein the temperature sensor senses a temperature of the heating line.

9. The heating jacket of claim 8, wherein, through the temperature of the heating line, which is transmitted by the temperature sensor, the temperature of the pipe is controlled so that a residual gas and/or a by-product gas of the semiconductor manufacturing equipment passing through the pipe is prevented from being fixed.

10. The heating jacket of claim 9, wherein, when an internal temperature of the pipe is controlled to be in a range of about 80° C. to about 180° C., an external temperature of the heating jacket is controlled to be no more than about 40° C.

11. A heating jacket provided on the outside of a pipe transferring a gas from semiconductor manufacturing equipment, the heating jacket comprising:
an internal shell wrapping an outer circumference of the pipe and having an insulation function;
a heating line arranged on an outside of the internal shell;
a vacuum insulation panel (VIP) wrapping an outside of the heating line; and
an external shell wrapping an external surface of the VIP and having an insulation function,
wherein the pipe comprises an upper level pipe and a lower level pipe,
wherein three or more heating jackets are vertically arranged on the upper level pipe, and
wherein a smaller number of heating jackets than that of heating jackets arranged on the upper level pipe is arranged on the lower level pipe.

12. The heating jacket of claim 11,
wherein temperature sensors are arranged in some of the three or more heating jackets on the upper level pipe, and
wherein temperature sensors are not arranged in others of the three or more heating jackets on the upper level pipe.

13. The heating jacket of claim 12, wherein the three or more heating jackets vertically contact one another without overlapping one another.

14. The heating jacket of claim 11, wherein a vertical length of the heating jacket is about 2 m.

15. The heating jacket of claim 11, wherein the three or more heating jackets are independently detachable from the pipe by vertically arranged fastening members, respectively.

16. A method of providing a heating jacket for semiconductor manufacturing equipment, the method comprising:
providing a plurality of heating jackets each including a heating line and a vacuum insulation panel (VIP) wrapping an outside of the heating line between an internal shell having an insulation function and an external shell having an insulation function;
arranging the plurality of heating jackets not to overlap one another so that an outside of a pipe, through which a gas is transferred from semiconductor manufacturing equipment, is wrapped; and
controlling a temperature of the pipe by applying predetermined power to the heating line,
wherein temperature sensors are arranged in some of the plurality of heating jackets, and
wherein temperature sensors are not arranged in the others of the plurality of heating jackets.

17. The method of claim 16, wherein, through the temperature of the heating line, which is transmitted by the temperature sensor, the temperature of the pipe is controlled so that a residual gas and/or a by-product gas of the semiconductor manufacturing equipment passing through the pipe is prevented from being fixed.

18. The method of claim 17, wherein, when an internal temperature of the pipe is controlled to be in a range of about 80° C. to about 180° C., an external temperature of the heating jacket is controlled to be no more than about 40° C.

19. The method of claim 16, wherein the pipe comprises an upper level pipe and a lower level pipe, wherein three or more heating jackets are vertically arranged on the upper level pipe, and wherein a smaller number of heating jackets than that of heating jackets arranged on the upper level pipe is arranged on the lower level pipe.

20. The method of claim 16, wherein the VIP includes glass fiber therein, wherein thermal conductivity of the VIP is about 0.002 W/m·k, and wherein the VIP is compressed to have density in a range of about 250 kg/m³ to about 300 kg/m³.
